(19) United States
(12) Patent Application Publication
(10) Pub. No.: US 2013/0062111 A1
(43) Pub. Date: Mar. 14, 2013

(54) STACKED SUBSTRATE MODULE

(71) Applicants: HSUN-FA LI, Nantou County (TW); YUN-TSUNG LI, Taichung City (TW); CHUN-CHI CHIU, Pingtung County (TW)

(72) Inventors: HSUN-FA LI, Nantou County (TW); YUN-TSUNG LI, Taichung City (TW); CHUN-CHI CHIU, Pingtung County (TW)

(73) Assignees: UNIVERSAL GLOBAL SCIENTIFIC INDUSTRIAL CO., LTD., NANTOU COUNTY (TW); UNIVERSAL SCIENTIFIC INDUSTRIAL ( SHANGHAI ) CO., LTD., SHANGHAI (CN)

(21) Appl. No.: 13/282,554

(22) Filed: Oct. 27, 2011

(30) Foreign Application Priority Data
Sep. 8, 2011 (TW) 100132410

(51) Int. Cl. H05K 1/11

(52) U.S. Cl. 174/263

(57) ABSTRACT

A stacked substrate module includes a first and a second substrate. The first substrate has several pads which extend respectively from a stacked area of the first substrate to the outside of the stacked area. The second substrate has several welding areas arranged on the outer lateral side thereof; each welding area extends respectively from the outer lateral side of the second substrate to an upper and a lower surface of the second substrate. The second substrate is stacked in the stacked area of the first substrate, wherein the lateral side of the second substrate is aligned to the edge of the stacked area of the first substrate. The aforementioned pads correspond to the welding areas respectively. It is suitable to position a solder paste between the pads and the welding areas which can be reflowed to connect the pads and the welding areas.

### BACKGROUND OF THE INVENTION

1. Field of the Invention

The instant disclosure relates to a substrate module; and more particularly, to a stacked substrate module.

2. Description of Related Art

Conventional dual-substrate module often comprises two substrates of the same dimension, in other words, the borders of the two substrates are substantially aligned to each other. Therefore, only the surface of the dual-substrate module corresponding to the circuit board may appear useful when the dual-substrate module is welded to a circuit board. This prevents the outer lateral side of the dual-substrate module from being welded, hence reducing the yield rate of welding the dual-substrate module. Furthermore, the welding result of the dual-substrate module also cannot be detected by visual observation

### SUMMARY OF THE INVENTION

One object of the instant disclosure is to provide a stacked substrate module, wherein the welding result of the stacked substrate module can be easily detected by visual observation.

The stacked substrate module in accordance with the instant disclosure includes a first and a second substrate. The first substrate has a plurality of pads which extends respectively from a stacked area of the first substrate to the outside of the stacked area. The second substrate has a plurality of welding areas arranged on the outer lateral side thereof, each welding area extends respectively from an outer lateral side of the second substrate to an upper and a lower surface of the second substrate. The second substrate is stacked in the stacked area of the first substrate, wherein the lateral side of the second substrate is aligned to the edge of the stacked area of the first substrate. The position of each pad y corresponds to each welding area, thereby enabling the positioning of a solder paste between the pads and the welding areas which can be reflowed to connect the pads and the welding areas.

In conclusion, as the instant disclosure provides a stacked substrate module where the second substrate is stacked in the stacked area of the first substrate, and the lateral side of the second substrate is aligned to the edge of the stacked area of the first substrate, this make it easy for the manufacturer to detect the welding result of the first and the second substrates by visual observation.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 is an exploded schematic view illustrating the stacked substrate module of the instant disclosure.

FIG. 2 is a plane schematic view illustrating the upper and the lower surfaces of the first substrate used for welding the electronic components of the instant disclosure.

FIG. 3 is a plane schematic view illustrating the solder paste disposed between the first and the second substrates of the instant disclosure.

FIG. 4 is a plane schematic view illustrating the solder paste welded between the first and the second substrates of the instant disclosure.

FIG. 5 is a three-dimensional schematic view illustrating the solder paste welded between the first and the second substrates of the instant disclosure.

FIG. 5A is a three-dimensional schematic view illustrating the solder paste welded between the first substrate and the L-shaped second substrate of the instant disclosure.

FIG. 6 is a three-dimensional schematic view illustrating the stacked substrate module used for welding on the circuit board of the instant disclosure.

FIG. 7 is a plane schematic view illustrating the solder paste disposed between the second substrate and the circuit board of the instant disclosure.

FIG. 8 is a plane schematic view illustrating the solder paste welded between the second substrate and the circuit board of the instant disclosure.

FIG. 9 is a three-dimensional schematic view illustrating the solder paste welded between the second substrate and the circuit board of the instant disclosure.

FIG. 10 is a three-dimensional schematic view illustrating the second embodiment of the instant disclosure.

### DETAILED DESCRIPTION OF THE PREFERRED EMBODIMENTS

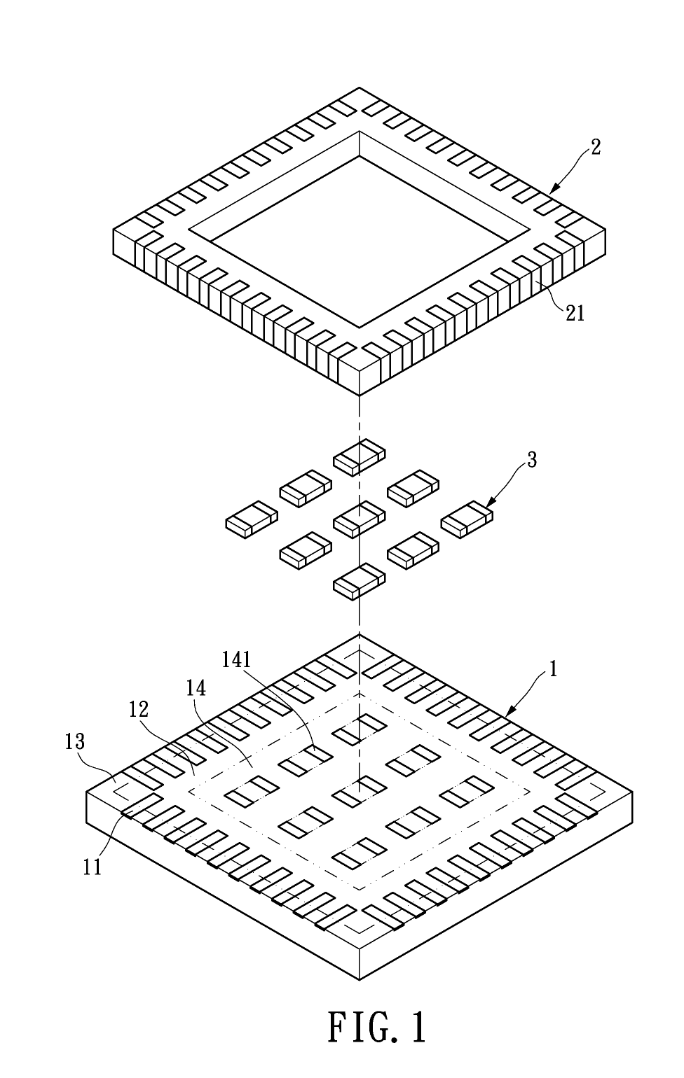

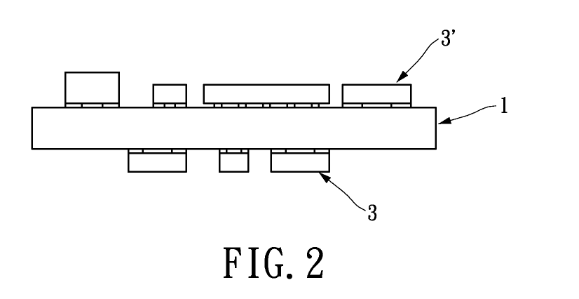

Please refer to FIGS. 1-9, which show the first embodiment of the instant disclosure, wherein FIGS. 1, 5, 5A, 6, and 9 are three-dimensional schematic view, and FIGS. 2 to 4, 7, and 8 are plane schematic view.

As shown in FIG. 1, the stacked substrate module includes a first substrate 1 and a second substrate 2 stacked upon each other. The first substrate 1 has a plurality of pads 11 which extends respectively from a stacked area 12 of the first substrate 1 to the outside of the stacked area 12.

More specifically, one surface of the first substrate 1 is divided into a detected area 13, the stacked area 12, and a component area 14. The detected area 13 is arranged on the outer side of the stacked area 12. The pads 11 extend respectively from the stacked area 12 to the detected area 13. The component area 14 is arranged on the inner side of the stacked area 12. The component area 14 has a plurality of pads 141 used for welding at least one electronic component 3, enabling the electronic component 3 to be welded on the component area 14. Additionally, the opposite surface of the first substrate 1 can also be used for welding at least one electronic component 3′ (shown in FIG. 2).

The contour of the second substrate 2 mainly corresponds to the stacked area 12 of the first substrate 1. The second substrate 2 has a plurality of welding areas 21 arranged on the outer lateral side thereof. Each welding area 21 extends from the outer lateral side of the second substrate 2 to an upper and a lower surface of the second substrate 2.

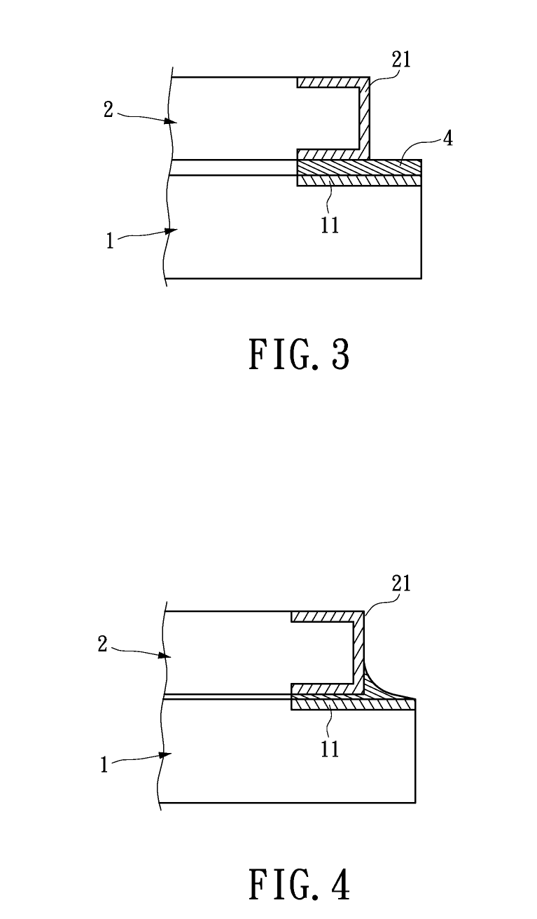

More specifically, the cross-section surface of each welding area 21 appears to be in U-shaped (shown in FIG. 3). In other words, each welding area 21 extends from the outer lateral side of the second substrate 2, bending in a direction to the upper and the lower surfaces of the second substrate 2, and the two portions of each welding area 21 arranged on the upper and the lower surfaces of the second substrate 2 are in mutual correspondence.

The second substrate 2 is stacked in the stacked area 12 of the first substrate 1, and the lateral side of the second substrate 2 is aligned to the edge of the stacked area 12 of the first substrate 1. Each position of the pad 11 corresponds to the welding area 21 respectively. Moreover, it is suitable to position a solder paste 4 between the pads 11 and the welding areas 21 (shown in FIG. 3) which can be reflowed to connect the pads 11 and the welding areas 21.

More specifically, the solder paste 4 disposed between the pads 11 and the welding areas 21 can be reflowed to form a solder fillet, where the solder fillet that extends to the welding areas 21 is arranged on the outer lateral side of the second substrate 2 (shown in FIG. 4) by the cohesion effect (a solder has the tendency to bond with a weldable material).

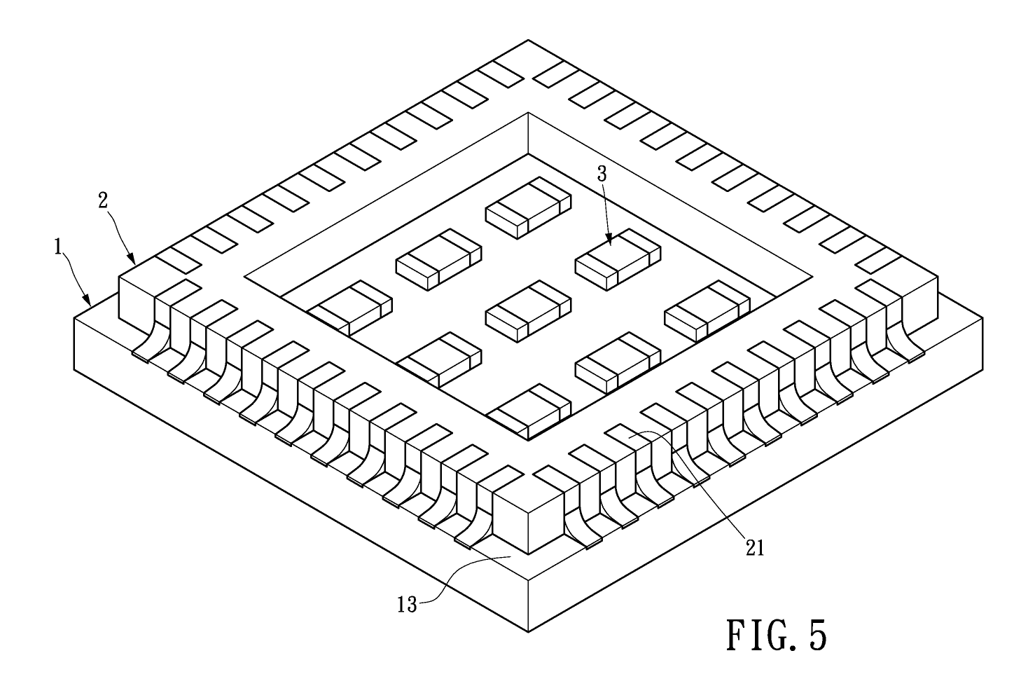

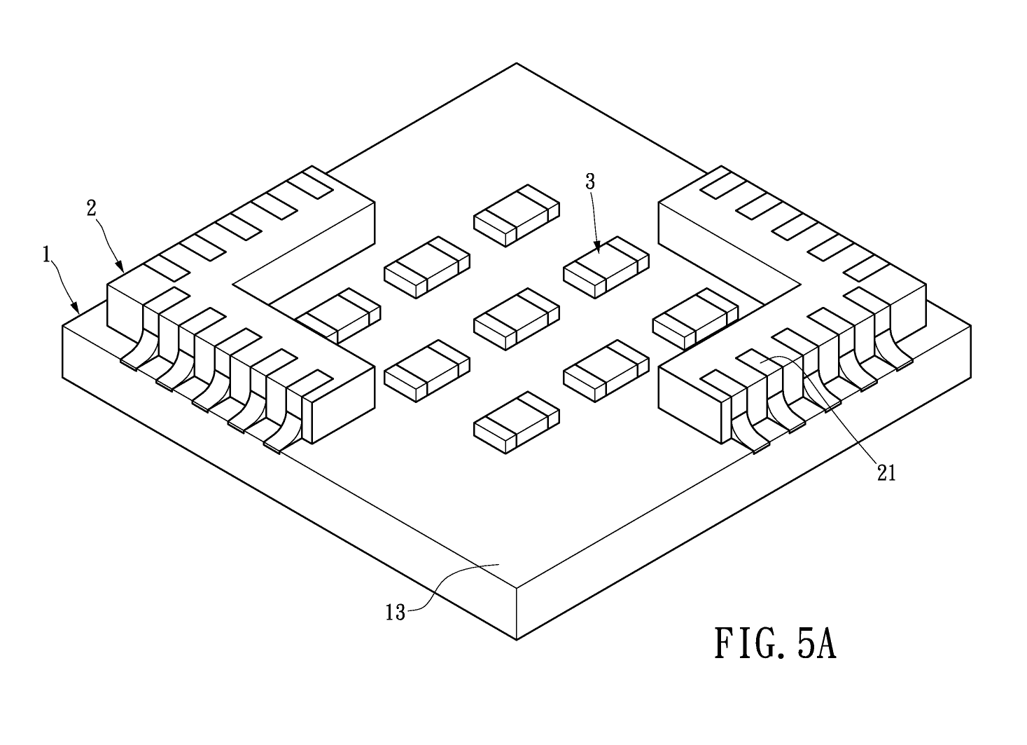

Thus, the connective area of the second substrate 2 is increased after the solder paste 4 is reflowed, enabling the combination of the first substrate 1 and the second substrate 2 to be firmer. Additionally, as shown in FIG. 5, the manufacturer can observe the solder fillet transformed from the solder paste 4 to find out if the solder fillet which extends to the welding areas 21 is arranged on the outer lateral side of the second substrate 2, so as to determine whether a fault (such as open) has occurred from the welding result of the first substrate 1 and the second substrate 2.

The second substrate 2 appears to be in a rectangular ring-shaped in the first embodiment. However, the shapes of the second substrate 2 can appear either in L-shaped, stripe-shaped, or other suitable shapes under practical applications. When the second substrate 2 appears to be in L-shaped, the stacked substrate module can be reflowed to form a structure shown in FIG. 5A.

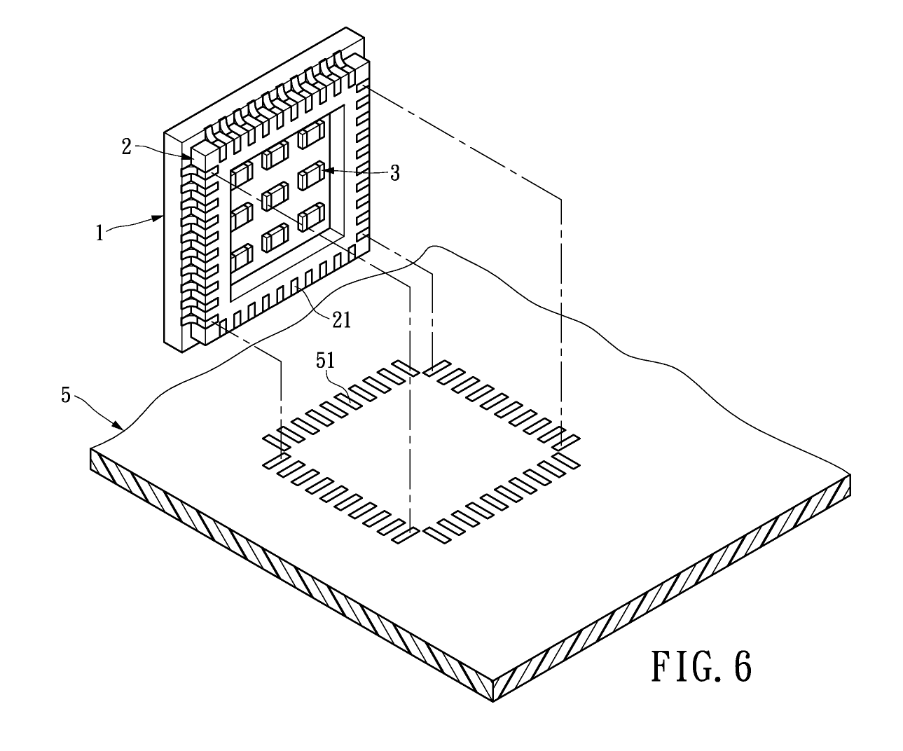

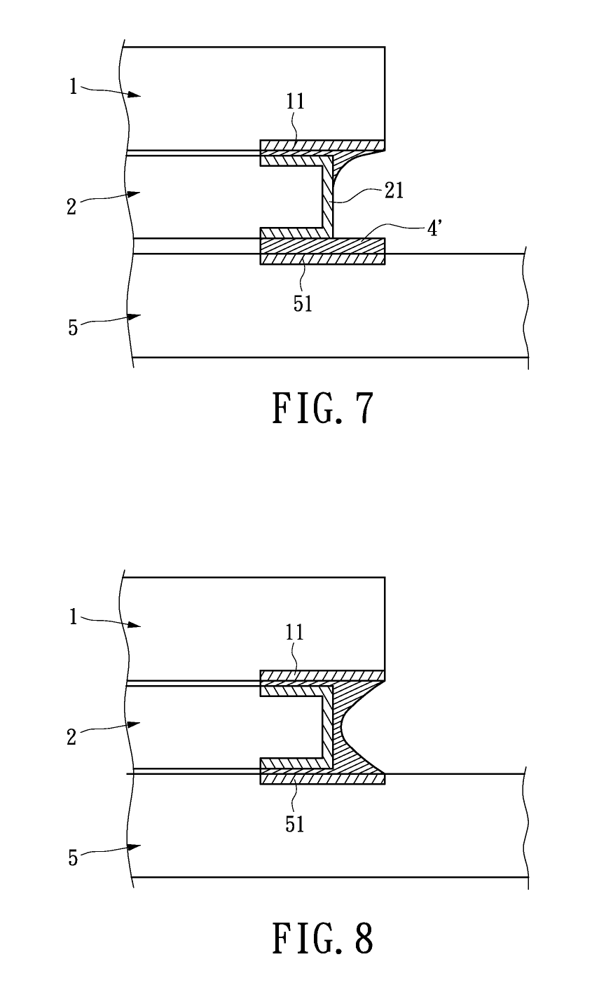

Please refer to FIGS. 6 and 7, one of the upper and the lower surface of the second substrate 2 is welded to the first substrate 1, and the opposite surface is used for welding to a circuit board 5. The circuit board 5 has a plurality of welding pads 51, the position and the shape of each welding pad 51 correspond to each pad 11 of the first substrate 1 respectively. It is suitable to position a solder paste 4′ between the welding pads 51 and the welding areas 21 which can reflow to connect the welding pads 51 and the welding areas 21.

More specifically, the solder paste 4′ disposed between the welding areas 21 and the welding pads 51 can be reflowed to form a solder fillet, wherein the solder fillet extends to the welding areas 21 arranged on the outer lateral side of the second substrate 2 (shown in FIG. 8) by the cohesion effect (a solder which has the tendency to bond with a weldable material).

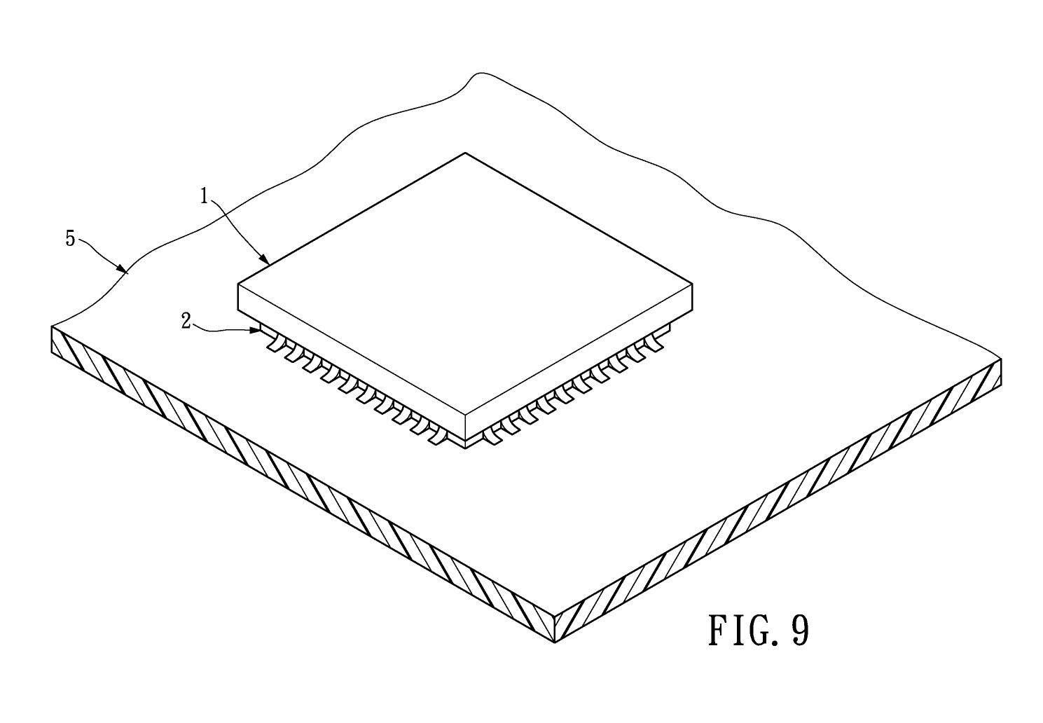

Thus, the connective area of the second substrate 2 is increased after the solder paste 4′ is being reflowed, enabling the combination of the circuit board 5 and the second substrate 2 to be firmer. Additionally, as shown in FIG. 9, the manufacturer can observe the solder fillet transformed from the solder paste 4′ to find out if the solder fillet which extends to the welding areas 21 is arranged on the outer lateral side of the second substrate 2, so as to determine whether a fault (such as open) has occurred from the welding result of the circuit board 5 and the second substrate 2.

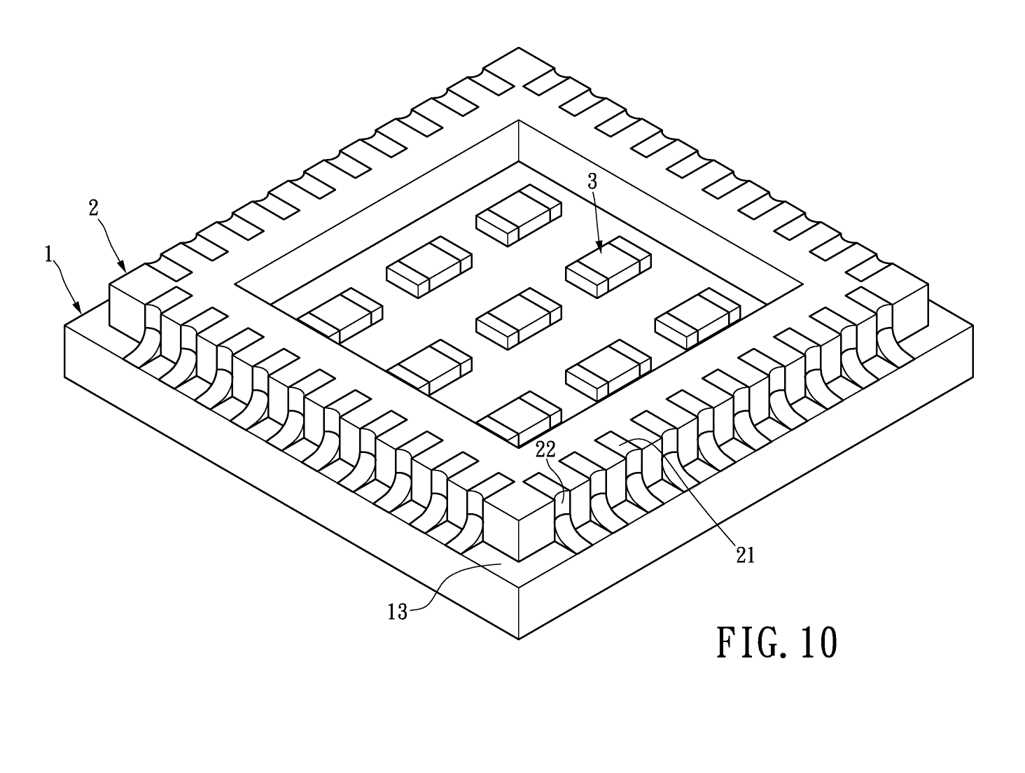

Please refer to FIG. 10, which shows the second embodiment of the instant disclosure. The differences between the first and the second embodiments are as follows.

The second substrate 2 has a plurality of troughs 22 concavely formed on the outer lateral side thereof. More specifically, the troughs 22 appear mainly to be in arc-shaped and are connected to the upper and the lower surfaces of the second substrate 2. The welding areas 21 are arranged on the troughs 22 and extended from the troughs 22 to the upper and the lower surfaces of the second substrate 2. Thus, the solder paste 4 (not shown) disposed between the pads 11 and the welding areas 21 can be reflowed to form a solder fillet, wherein the solder fillet extends to the welding areas 21 arranged on the troughs 22 of the second substrate 2, whereby the connective area of the second substrate 2 is increased, enabling the combination of the first substrate 1 and the second substrate 2 to be firmer.

Likewise, when the second substrate 2 is welded on the circuit board 5 (not shown), the solder paste 4′ disposed between the welding areas 21 and the welding pads 51 can be reflowed to form a solder fillet, wherein the solder fillet extends to the welding areas 21 arranged on the troughs 22 of the second substrate 2. Thus, the connective area of the second substrate 2 is increased, enabling the combination of the circuit board 5 and the second substrate 2 to be firmer.

The instant disclosure provides several advantages. Firstly, the aforementioned stacked substrate module can extend to the welding areas 21 arranged on the outer lateral sides of the substrate 2 by using the solder fillet transformed from the solder paste 4 and 4′ when being reflowed, enabling the combination of the upper and the lower surfaces of the second substrate 2 to connect firmly with the first substrate 1 and the circuit board 5 respectively.

Secondly, the manufacturer can observe the solder fillet transformed from the solder paste 4 (or the solder paste 4′) to find out if the solder fillet is extending to the welding areas 21 arranged on the outer lateral side of the second substrate 2, whereby the manufacturer can determine if a fault (such as open) has occurred from the welding result of the second substrate 2 and the first substrate 1/circuit board 5.

Thirdly, the connective area of the second substrate 2 can be increased though the design of the troughs 22 of the second substrate 2, thus allowing the upper and the lower surfaces of the second substrate 2 to be firmly connected to the first substrate 1 and the circuit board 5.

The description above only illustrates specific embodiments and examples of the instant disclosure. The instant disclosure should therefore cover various modifications and variations made to the herein-described structure and operations of the instant disclosure, provided they fall within the scope of the instant disclosure as defined in the following appended claims.

What is claimed is:

1. A stacked substrate module, comprising:
a first substrate having a plurality of pads which extends respectively from a stacked area of the first substrate to the outside of the stacked area; and
a second substrate having a plurality of welding areas arranged on the outer lateral side thereof, each of the welding areas extends respectively from the outer lateral side of the second substrate to an upper and a lower surfaces of the second substrate,
wherein the second substrate is stacked on the stacked area of the first substrate and the lateral side of the second substrate is aligned to the edge of the stacked area of the first substrate,
wherein the position of each pad corresponds to each welding area, thereby enabling the positioning of a solder paste between the pads and the welding areas,
wherein the solder paste is reflowed to establish connection between the pads and the welding areas.

2. The stacked substrate module as claimed in claim 1, wherein the solder paste disposed between the pads and the welding areas is reflowed to form a solder fillet, wherein the solder fillet extends to the welding areas arranged on the outer lateral side of the second substrate.

3. The stacked substrate module as claimed in claim 2, wherein the first substrate has a detected area arranged on the outside of the stacked area, the pads extend from the stacked area to the detected area respectively.

4. The stacked substrate module as claimed in claim 1, wherein the first substrate has a component area arranged within the stacked area, the component area of the first substrate is used for welding at least one electronic component.

5. The stacked substrate module as claimed in claim 1, wherein each welding area extends from the outer lateral side of the second substrate and is bent in a direction toward the upper and the lower surfaces of the second substrate.

6. The stacked substrate module as claimed in claim 1, wherein the cross-section surface of each welding area is substantially U-shaped, and the two portions of each welding area arranged on the upper and the lower surfaces of the second substrate are in mutual correspondence.

7. The stacked substrate module as claimed in claim 1, wherein one of the upper or the lower surfaces of the second substrate is welded to the first substrate and the opposite surface is used for welding to a circuit board.

8. The stacked substrate module as claimed in claim 7, wherein the circuit board has a plurality of welding pads, the position and the shape of each welding pad correspond to each pad of the first substrate respectively, wherein the space between the welding areas of the second substrate and the welding pads of the circuit board is suitable for disposing a solder paste, wherein the solder paste is reflowed to establish connection between the welding areas and the welding pads.

9. The stacked substrate module as claimed in claim 8, wherein the solder paste disposed between the welding areas and the welding pads is reflowed to form a solder fillet, wherein the solder fillet extends to the welding areas arranged on the outer lateral side of the second substrate.

10. The stacked substrate module as claimed in claim 1, wherein the second substrate has a plurality of troughs concavely formed on the outer lateral side thereof, wherein the troughs is substantially arc-shaped and are connected to the upper and the lower surfaces of the second substrate, wherein the welding areas are arranged on the troughs and extended from the troughs to the upper and the lower surfaces of the second substrate.
